(19) United States
(12) Patent Application Publication
(10) Pub. No.: US 2023/0371198 A1
(43) Pub. Date: Nov. 16, 2023

(54) COOLING DEVICE

(71) Applicant: Panasonic Intellectual Property Management Co., Ltd., Osaka (JP)

(72) Inventors: Manabu CHIKAYAMA, Osaka (JP); Toshihiko MATSUDA, Osaka (JP)

(21) Appl. No.: 18/141,057

(22) Filed: Apr. 28, 2023

(30) Foreign Application Priority Data
May 10, 2022 (JP) 2022-077742

(51) Int. Cl. H05K 7/20

(52) U.S. Cl. CPC H05K 7/20254; H05K 7/20263

(57) ABSTRACT

A cooling device includes a base material providing a heating element on a first surface and a heat exchanger on a second surface opposite to the first surface, the heat exchanger receiving heat from the heating element to perform heat exchange with a refrigerant, and a case material including a refrigerant inflow port and a refrigerant outflow port, the refrigerant inflow port supplying the refrigerant to the heat exchanger. The case material is attachable to the base material in two forms of a first form and a second form, the first form being a form in which the refrigerant inflow port and the refrigerant outflow port are attached to the base material in a first direction, and the second form being a form in which the refrigerant inflow port and the refrigerant outflow port are attached to the base material in a second direction different from the first direction.

### BACKGROUND

### 1. Technical Field

The present disclosure relates to a cooling device for use in a cooling system for cooling a heating element.

### 2. Description of the Related Art

FIG. 1 is a schematic view illustrating a configuration of liquid-cooled cooling system 50 including cooling device 10 using a refrigerant for cooling heating element 1. In the cooling system for cooling heating element 1, for example, a cooling device including a heat exchanger for exchanging heat from heating element 1 with the refrigerant is arranged between pump 20 and heat dissipator 30, the refrigerant is supplied to the cooling device, the heat is received by the refrigerant, the heat is dissipated by heat dissipator 30 to cool the refrigerant, and the refrigerant is circulated via pump 20.

In a case where the heating element is, for example, a member such as a digital micromirror device (DMD) in a display used in a projector, it is necessary to avoid physical interference with an electrical contact such as a board on which the DMD is arranged. Thus, a heat receiver of the cooling device in contact with the heating element needs to be limited to a part.

For example, a cooling device and a heat reception member for an electronic device in which a heating element is arranged in a lower portion and a refrigerant is supplied from an upper portion for cooling are disclosed (see, for example, Patent Literature (PTL) 1).

PTL 1: Japanese Patent No. 4876975

### SUMMARY

It is preferable that the heat exchanger such as a fin for conducting heat from the heat receiver is arranged in a fixed manner. By contrast, in the cooling system, the arrangement of a pipe of the refrigerant may be limited as illustrated in part (a) of FIG. 12 in the pipe connected to the cooling device. Thus, in a case where a relationship between the arrangement of the cooling system and orientations of the heat receiver and the pipe of the refrigerant are not appropriate, there is a problem that the pipe of the refrigerant becomes redundant or cannot be used due to interference with a place where the pipe is to be arranged.

Thus, an object of the present disclosure is to provide a cooling device capable of appropriately changing an orientation of a pipe of a refrigerant.

A cooling device according to the present disclosure includes a base material providing a heating element on a first surface and a heat exchanger on a second surface opposite to the first surface, the heat exchanger receiving heat from the heating element to perform heat exchange with a refrigerant, and a case material including a refrigerant inflow port and a refrigerant outflow port, the refrigerant inflow port supplying the refrigerant to the heat exchanger of the base material. The case material is attachable to the base material in two forms of a first form and a second form, the first form being a form in which the refrigerant inflow port and the refrigerant outflow port are attached to the base material in a first direction, and the second form being a form in which the refrigerant inflow port and the refrigerant outflow port are attached to the base material in a second direction different from the first direction.

According to the cooling device according to the present disclosure, the orientation of the pipe of the refrigerant can be appropriately changed. Accordingly, it is possible to cope with arrangements of various cooling systems.

### BRIEF DESCRIPTION OF THE DRAWINGS

FIG. 1 is a schematic view illustrating a configuration of a cooling system including a cooling device that cools a heating element;

FIG. 2 is a schematic perspective view illustrating an outer appearance of a cooling device according to a first exemplary embodiment;

FIG. 3 is an exploded perspective view illustrating an outline of main constituent members of the cooling device of FIG. 2;

FIG. 4 is a schematic perspective view illustrating a configuration of a back surface of a base material constituting the cooling device according to the first exemplary embodiment;

FIG. 5 is a schematic perspective view illustrating an outline of a first case material constituting the cooling device according to the first exemplary embodiment;

FIG. 6 is a schematic perspective view illustrating an outline of a second case material constituting the cooling device according to the first exemplary embodiment;

FIG. 7 is a schematic cross-sectional view illustrating a flow of a refrigerant in a cross section perpendicular to an inflow direction of the refrigerant from a refrigerant inflow port in the cooling device of FIG. 2;

FIG. 8 is a schematic cross-sectional view illustrating a flow of the refrigerant in a cross section parallel to the inflow direction of the refrigerant from the refrigerant inflow port in the cooling device of FIG. 2;

FIG. 9 is a schematic cross-sectional view illustrating a flow of the refrigerant in a cross section parallel to an outflow direction of the refrigerant to a refrigerant outflow port in the cooling device of FIG. 2;

FIG. 10A is a plan view illustrating a relationship between bolts constituting the cooling device of FIG. 2 and bolt holes of the base material;

FIG. 10B is a perspective plan view illustrating bolt holes of the second case material in a state where the base material constituting the cooling device of FIG. 2 is made transparent;

FIG. 11A is a schematic perspective view illustrating an outer appearance of the cooling device in a case where the bolt holes of the base material of FIG. 10A and the bolt holes of the second case material of FIG. 10B are combined and bolted in a first form (0°);

FIG. 11B is a schematic perspective view illustrating an outer appearance of the cooling device in a case where the bolt holes of the base material of FIG. 10A and the bolt holes of the second case material of FIG. 10B are combined and bolted in a second form (120°); and

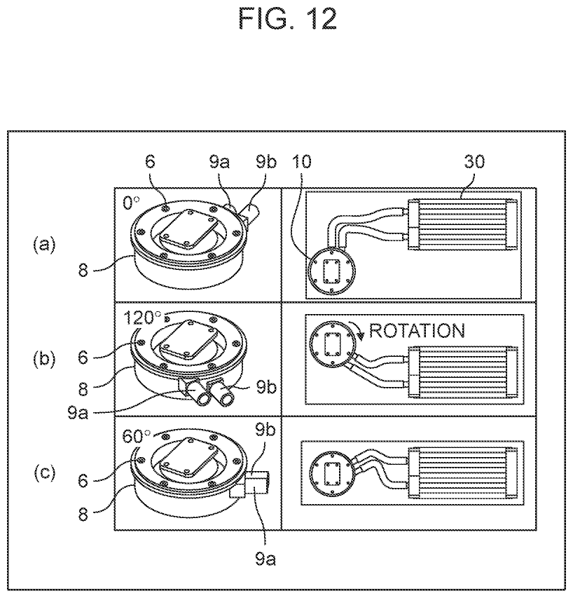

Part (a) of FIG. 12 is a schematic view illustrating an outer appearance of the cooling device and a connection example with a heat dissipator in a case where the cooling device is combined and bolted in the first mode (0°) of FIG. 11A, Part (b) of FIG. 12 is a schematic view illustrating an outer appearance of the cooling device and a connection example with the heat dissipator in a case where the cooling device is combined and bolted in the second mode (120°) of FIG. 11B, and part (c) of FIG. 12 is a schematic view illustrating an outer appearance of the cooling device and a connection example with the heat dissipator in a case where the cooling device is combined and bolted in a third mode (60°).

### DETAILED DESCRIPTIONS

A cooling device according to a first aspect includes a base material providing a heating element on a first surface and a heat exchanger on a second surface opposite to the first surface, the heat exchanger receiving heat from the heating element to perform heat exchange with a refrigerant, and a case material including a refrigerant inflow port and a refrigerant outflow port, the refrigerant inflow port supplying the refrigerant to the heat exchanger of the base material. The case material is attachable to the base material in two forms of a first form and a second form, the first form being a form in which the refrigerant inflow port and the refrigerant outflow port are attached to the base material in a first direction and a second form being a form in which the refrigerant inflow port and the refrigerant outflow port are attached to the base material in a second direction different from the first direction.

In a cooling device according to a second aspect, in the first aspect, the heat exchanger may include a plurality of fins arranged substantially in parallel.

In a cooling device according to a third aspect, in the first or second aspect, the case material may include a first case material and a second case material, the first case material may cause the refrigerant to flow through the heat exchanger, and the second case material may include the refrigerant inflow port and the refrigerant outflow port, and is attached to the base material while holding the first case material.

In the cooling device according to a fourth aspect, in the third aspect, the base material may include a plurality of first bolt holes arranged along a circumference, the case material may include a plurality of second bolt holes corresponding to the plurality of first bolt holes, and the base material and the case material may be attachable in the first form by bolting the plurality of first bolt holes and the plurality of second bolt holes to correspond to the first form, and the base material and the case material are attachable in the second form by bolting the plurality of first bolt holes and the plurality of second bolt holes to correspond to the second form.

In a cooling device according to a fifth aspect, in the fourth aspect, the plurality of first bolt holes may be arranged at equal intervals along the circumference.

In a cooling device according to a sixth aspect, in the fourth aspect, the second case material may include a cylindrical groove through which the refrigerant flows in a center and a annular groove through which the refrigerant flows in an outer peripheral direction in a concentric circle with the cylindrical groove, the cylindrical groove may be connected to the refrigerant inflow port, and the annular groove may be connected to the refrigerant outflow port.

In a cooling device according to a seventh aspect, in the sixth aspect, the first case material may define a flow path of the refrigerant from the cylindrical groove of the second case material to the heat exchanger, and may define a flow path of the refrigerant from the heat exchanger to the annular groove.

In the cooling device according to an eighth aspect, in the third aspect, the base material and the case material may be gripped by a gripping member.

Hereinafter, a cooling device according to an exemplary embodiment will be described with reference to the accompanying drawings. Note that, in the drawings, substantially the same members are designated by the same reference marks.

### First Exemplary Embodiment

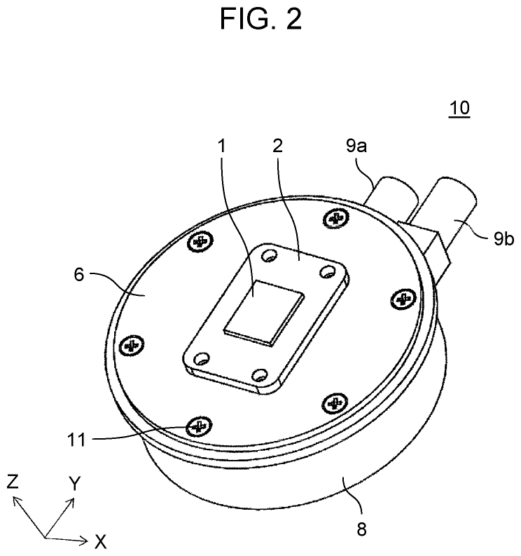

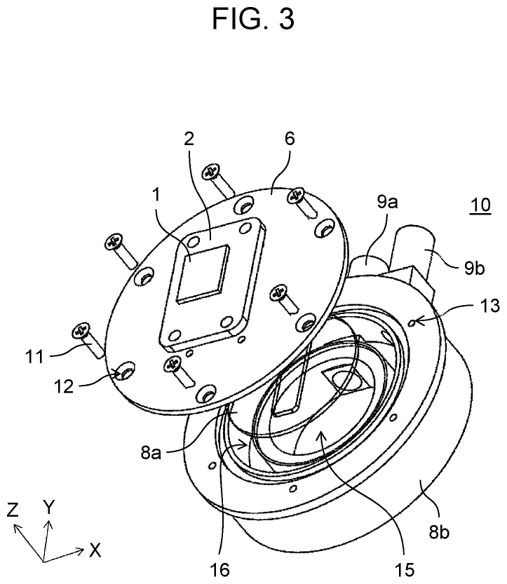

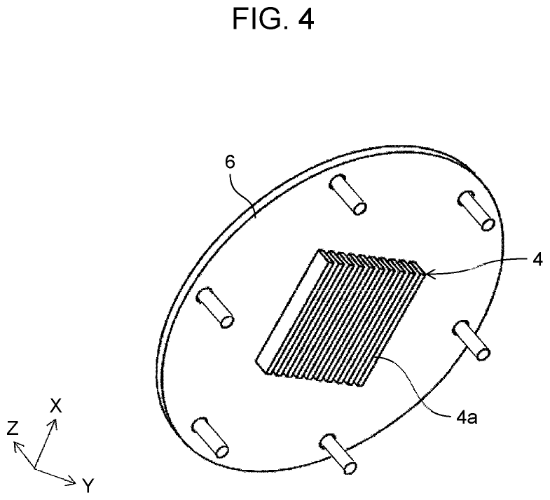

FIG. 2 is a schematic perspective view illustrating an outer appearance of cooling device 10 according to a first exemplary embodiment. FIG. 3 is an exploded perspective view illustrating an outline of main constituent members of cooling device 10 of FIG. 2. FIG. 4 is a schematic perspective view illustrating a configuration of a back surface (second surface) of base material 6 constituting cooling device 10 according to the first exemplary embodiment. Note that, in the drawings, for the sake of convenience, a plane of base material 6 on which heating element 1 is arranged is an XY plane, a direction perpendicular to the XY plane is a Z direction, and a direction in which refrigerant inflow port 9a and refrigerant outflow port 9b are provided in FIG. 2 is indicated as a Y direction. In addition, a direction perpendicular to the Y direction on the XY plane is defined as an X direction.

Cooling device 10 according to the first exemplary embodiment includes base material 6 in which a heating element 1 is arranged on a first surface and heat exchanger 4 that performs heat exchange with a refrigerant is provided on a second surface, and case material 8 (first case material 8a and second case material 8b) including refrigerant inflow port 9a and refrigerant outflow port 9b that supply the refrigerant to heat exchanger 4 of base material 6. The second surface is a surface opposite to the first surface. In addition, heat exchanger 4 receives heat from heating element 1 and exchanges heat with the refrigerant. Case material 8 can be attached to base material 6 in two forms of a first form in which refrigerant inflow port 9a and refrigerant outflow port 9b are attached in a first direction and a second form in which refrigerant inflow port 9a and refrigerant outflow port 9b are attached in a second direction different from the first direction. With the above configuration, an orientation of a pipe of the refrigerant can be appropriately changed. Accordingly, it is possible to cope with the arrangement of various cooling systems for heating elements such as displays and electronic components.

Hereinafter, each member constituting cooling device 10 will be described.

<Heating Element>

Heating element 1 is, for example, a digital micromirror device (DMD) in a display. In addition, the heating element may be an electronic component. Note that, heating element 1 is not limited to the above example.

<Heat Receiver>

Heat receiver 2 comes into contact with heating element 1 to receive heat. In addition, heat receiver 2 is provided on a front surface (first surface) of base material 6, and transfers heat to heat exchanger 4 provided on the back surface (second surface) by heat conduction. A shape of heat receiver 2 is rectangular in FIGS. 2 and 3 and the like, but is not limited thereto, and may be any shape as long as the heat receiver can be in contact with heating element 1. For example, the shape may be a polygon, a circle, an ellipse, or the like.

<Base Material>

As illustrated in FIG. 3, in base material 6, heating element 1 is arranged on the first surface (front surface), and as illustrated in FIG. 4, heat exchanger 4 that moves heat from heating element 1 to the refrigerant is provided on the second surface (back surface) opposite to the first surface.

In addition, base material 6 is bolted to case material 8 (second case material 8b) with a plurality of bolt holes 12 (an example of first bolt holes) arranged along a circumference by bolts 11. For example, the plurality of bolt holes 12 are provided at equal intervals along the circumference. Note that, the attachment of base material 6 and case material 8 is not limited to the case of using the bolts. For example, base material 6 and case material 8 may be attached by a gripping member such as a leaf spring.

<Heat Exchanger>

Heat exchanger 4 has, for example, a shape in which a plurality of fins 4a each having a plate-shape are arranged substantially in parallel. The refrigerant flows between the plurality of fins 4a. Heat exchanger 4 is provided on the back surface (second surface) of base material 6 and receives heat from heating element 1 and heat receiver 2 arranged on the front surface (first surface). The plurality of fins 4a have substantially the same shape and are arranged substantially in parallel. For example, microfins may have a pitch of 0.2 mm to 0.3 mm. Note that, heat exchanger 4 is not limited to the above case. For example, the fin may be a round columnar fin instead of the plate-shaped fin. In this case, for example, the columnar fins may be arranged in a square lattice shape, a triangular lattice shape, or the like. Alternatively, the fins may be arranged randomly.

In addition, fins 4a of heat exchanger 4 can be appropriately formed and arranged in accordance with configurations and shapes of heating element 1 and heat receiver 2. In this case, the arrangement of heating element 1 and fins 4a of heat exchanger 4 is a specific arrangement. Thus, a direction of base material 6 including heat exchanger 4 may be set to a predetermined direction with respect to heating element 1.

<Case Material>

As illustrated in FIG. 3, case material 8 includes refrigerant inflow port 9a and refrigerant outflow port 9b for supplying the refrigerant to heat exchanger 4 of base material 6. In case material 8, refrigerant inflow port 9a and refrigerant outflow port 9b can be attached to base material 6 in a plurality of directions. Specifically, case material 8 can be attached to base material 6 in two forms of the first form in which refrigerant inflow port 9a and refrigerant outflow port 9b are attached in the first direction and the second form in which refrigerant inflow port 9a and refrigerant outflow port 9b are attached in the second direction different from the first direction. Case material 8 includes first case material 8a and second case material 8b.

<First Case Material>

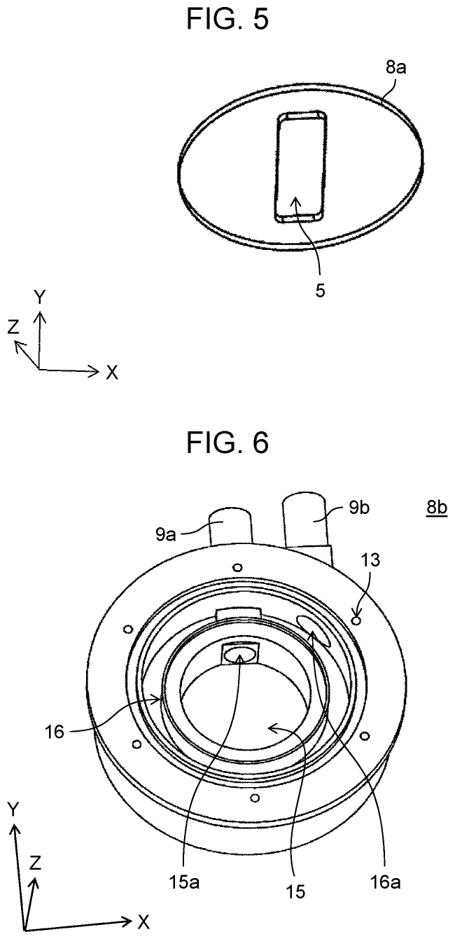

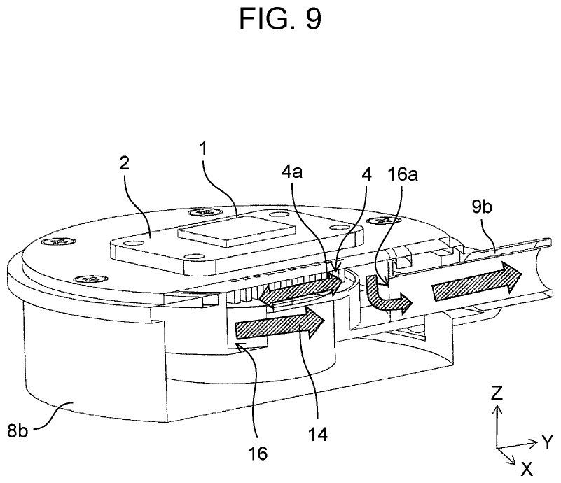

FIG. 5 is a schematic perspective view illustrating an outline of first case material 8a constituting cooling device 10 according to the first exemplary embodiment. First case material 8a is arranged between heat exchanger 4 and second case material 8b of base material 6, and causes the refrigerant to flow along heat exchanger 4 via opening 5. First case material 8a is, for example, a rubber sheet made of rubber. First case material 8a is in close contact with upper surfaces of the plurality of fins 4a to guide the refrigerant from opening 5 to a flow path between fins 4a (to be described later with reference to FIGS. 7 to 9). Accordingly, it is possible to prevent the refrigerant flowing from refrigerant inflow port 9a from flowing out without passing through a groove between fins 4a of heat exchanger 4 and without exchanging heat.

<Second Case Material>

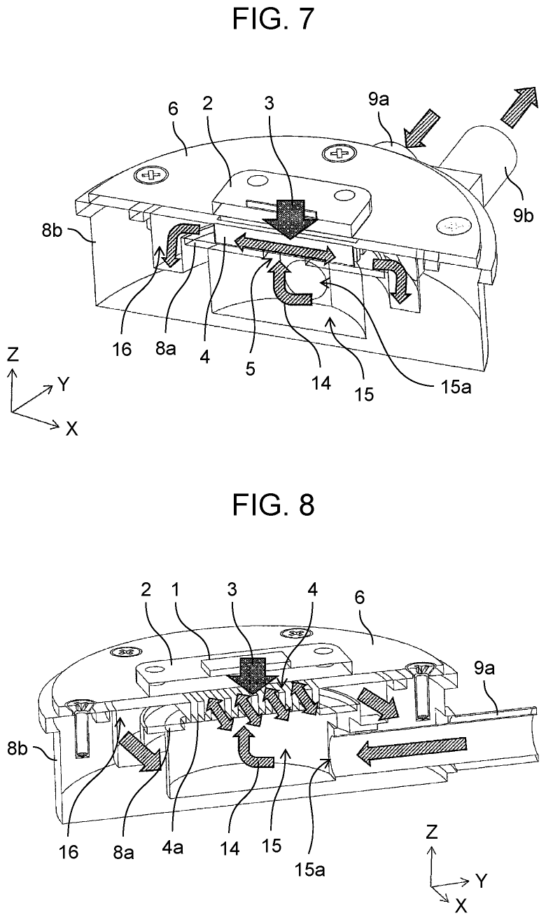

FIG. 6 is a schematic perspective view illustrating an outline of second case material 8b constituting cooling device 10 according to the first exemplary embodiment. Second case material 8b includes refrigerant inflow port 9a and refrigerant outflow port 9b, and can be attached to base material 6 in the plurality of directions while first case material 8a is held. Second case material 8b includes cylindrical groove 15 having a cylindrical shape through which the refrigerant flows in a center, and annular groove 16 having an annular shape through which the refrigerant flows in an outer periphery direction in a concentric circle with cylindrical groove 15. Cylindrical groove 15 is connected to refrigerant inflow port 9a, and annular groove 16 is connected to refrigerant outflow port 9b. For example, a “spot face” into which first case material 8a is fitted may be provided in second case material 8b. First case material 8a and second case material 8b can define a flow path of the refrigerant from heat exchanger 4 to annular groove 16 of second case material 8b.

In addition, second case material 8b also includes a plurality of bolt holes 13 (an example of second bolt holes) arranged along a circumference. Base material 6 and case material 8 can be attached by bolting bolt holes 12 of base material 6 and bolt holes 13 of second case material 8b with bolts 11 in correspondence with each other. Note that, for example, an O-ring rubber insertion groove for preventing water leakage is provided on each of opposing surfaces of base material 6 and case material 8.

<Refrigerant Outflow and Inflow Ports>

As illustrated in FIGS. 2 and 3, refrigerant inflow port 9a and refrigerant outflow port 9b may be arranged in the same Y direction. Alternatively, refrigerant inflow port 9a and refrigerant outflow port 9b may be arranged in different directions. For example, refrigerant inflow port 9a and refrigerant outflow port 9b may be arranged in a +Y direction and a −Y direction, respectively, with second case material 8b interposed therebetween.

<Flow of Refrigerant>

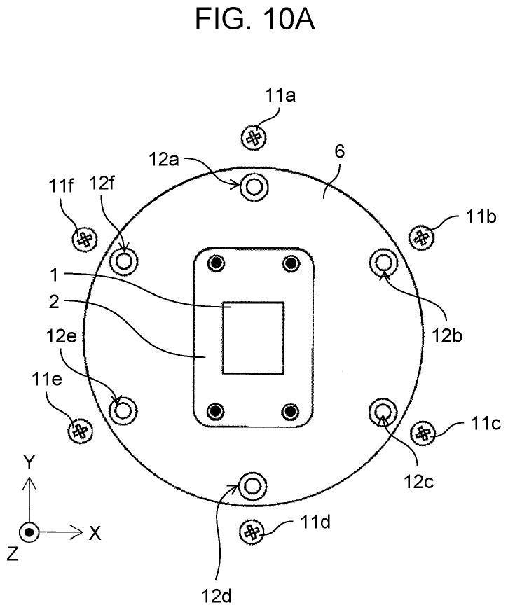

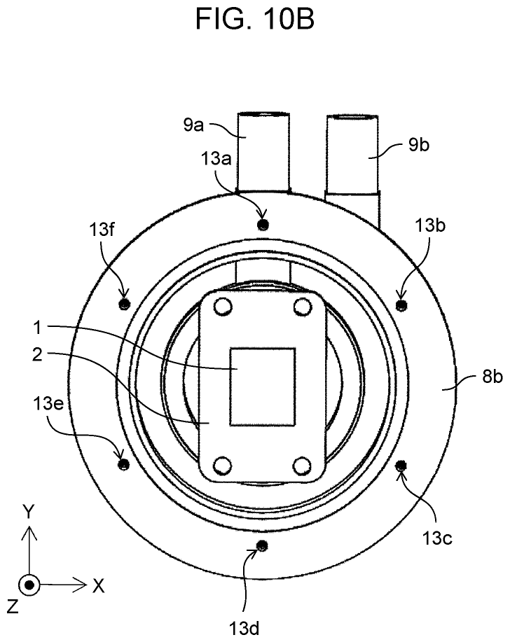

FIG. 7 is a schematic cross-sectional view illustrating a flow of refrigerant 14 in a cross section perpendicular to an inflow direction of refrigerant 14 from refrigerant inflow port 9a in cooling device 10 of FIG. 2. FIG. 8 is a schematic cross-sectional view illustrating a flow of refrigerant 14 in a cross section parallel to the inflow direction of refrigerant 14 from refrigerant inflow port 9a in cooling device 10 of FIG. 2. FIG. 9 is a schematic cross-sectional view illustrating a flow of refrigerant 14 in a cross section parallel to an outflow direction of refrigerant 14 to refrigerant outflow port 9b in cooling device 10 of FIG. 2. Refrigerant 14 is, for example, an antifreeze. In addition, ethylene glycol, propylene glycol, and the like can be used. Note that, the present invention is not limited to the above example.

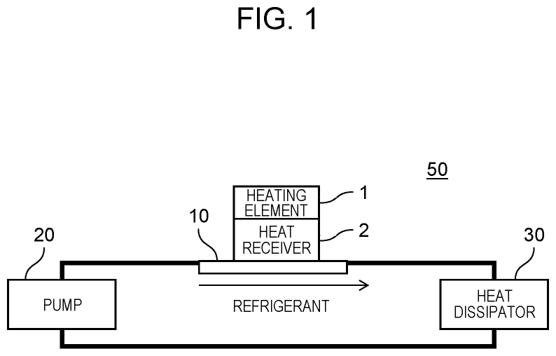

Refrigerant 14 flowing from refrigerant inflow port 9a is guided to cylindrical groove 15 at a center of second case material 8b via inlet 15a. Refrigerant 14 guided to cylindrical groove 15 is guided between fins 4a arranged substantially parallel to heat exchanger 4 via opening 5 of first case material 8a arranged above in the Z direction. Refrigerant 14 guided between fin 4a flows in both a +X direction and a −X direction along an extending direction of fin 4a. At this time, heat 3 flowing from heating element 1 to heat receiver 2 and then flowing from heat receiver 2 to fin 4a transfers from fin 4a to refrigerant 14. Thereafter, refrigerant 14 enters annular groove 16 provided on an outer periphery in the concentric circle with cylindrical groove 15 from both ends of fin 4a, goes around an outer periphery along annular groove 16, and flows out from refrigerant outflow port 9b via outlet 16a. For example, as illustrated in FIG. 1, refrigerant 14 dissipates heat at heat dissipator 30 via a pipe, and circulates to cooling device 10 via pump 20.

Note that, as illustrated in FIGS. 8 and 9, a height of refrigerant inflow port 9a in the Z direction and a height of refrigerant outflow port 9b in the Z direction are higher at refrigerant outflow port 9b than at refrigerant inflow port 9a, but the present invention is not limited thereto. Both the heights may be the same. Alternatively, the heights may be reversed.

In addition, a direction in which refrigerant 14 flows is not limited to the above direction. Refrigerant 14 may flow in, for example, an opposite direction. In this case, the reference marks of the refrigerant inflow port and the refrigerant outflow port may be switched.

<Arrangement of Base Material and Case Material>

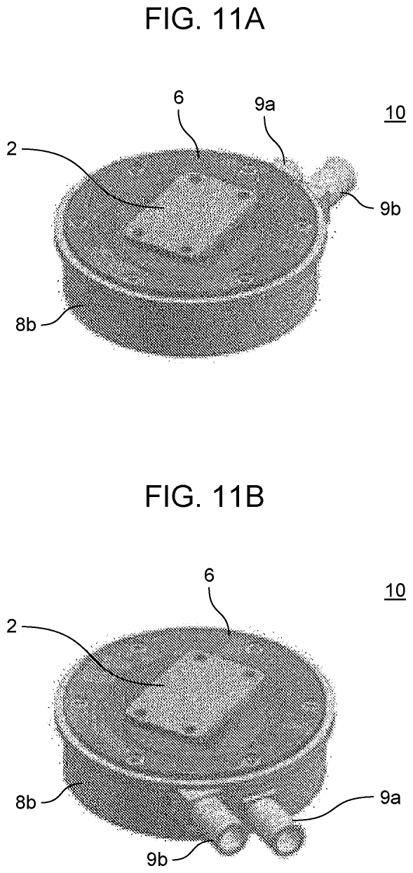

FIG. 10A is a plan view illustrating a relationship between bolts 11a to 11f constituting cooling device 10 in FIG. 2 and bolt holes 12a to 12f of base material 6. FIG. 10B is a perspective plan view illustrating bolt holes 13a to 13f of second case material 8b in a state where the base material constituting cooling device 10 of FIG. 2 is made transparent. FIG. 11A is a schematic perspective view illustrating an outer appearance of the cooling device in a case where bolt holes 12a to 12f of base material 6 in FIG. 10A and bolt holes 13a to 13f of second case material 8b in FIG. 10B are combined and bolted in a first form (0°). FIG. 11B is a schematic perspective view illustrating an outer appearance of the cooling device in a case where bolt holes 12a to 12f of base material 6 in FIG. 10A and bolt holes 13a to 13f of second case material 8b in FIG. 10B are combined and bolted in a second form (120°).

Here, the first form (0°) refers to a case where refrigerant inflow port 9a and refrigerant outflow port 9b are attached in the first direction (+Y direction). In this case, base material 6 and case material 8 can be attached in the first form by bolting bolt holes 12a to 12f of base material 6 and bolt holes 13a to 13f of second case material 8b with bolts 11a to 11f in association with each other.

In addition, the second form (120°) refers to a case where refrigerant inflow port 9a and refrigerant outflow port 9b are attached in the second direction (direction forming 120° from the +Y direction). In this case, base material 6 and case material 8 can be attached in the second form by bolting bolt holes 12a to 12f of base material 6 and bolt holes 13e, 13f, and 13a to 13d of second case material 8b with bolts 11a to 11f in association with each other. In this case, bolt hole 13a of second case material 8b is bolted with bolt hole 12c of base material 6 in association with each other.

Further, a third form (60°) refers to a case where refrigerant inflow port 9a and refrigerant outflow port 9b are attached in a third direction (direction forming 60° from the +Y direction). In this case, base material 6 and case material 8 can be attached in the third form by bolting bolt holes 12a to 12f of base material 6 and bolt holes 13f and 13a to 13e of second case material 8b with bolts 11a to 11f in association with each other. In this case, bolt hole 13a of second case material 8b is bolted with bolt hole 12b of base material 6 in association with each other.

As described above, base material 6 and case material 8 are attached not only in the first form (0°) but also in the second form (120°) and the third form (60°). Accordingly, refrigerant inflow port 9a and refrigerant outflow port 9b can be directed not only in the first direction (+Y direction) but also in the second direction (direction forming 120° from the +Y direction) and the third direction (direction forming 60° from the +Y direction). Thus, as compared with a case where the pipe of the refrigerant can be directed only in a predetermined direction with respect to heating element 1, the orientation of the refrigerant pipe can be changed, and it is also possible to cope with the restriction of the arrangement of the cooling system.

Part (a) of FIG. 12 is a schematic view illustrating an outer appearance of the cooling device and a connection example with the heat dissipator in a case where the bolt holes and the bolts are combined and bolted in the first form (0°) of FIG. 11A. Part (b) of FIG. 12 is a schematic view illustrating an outer appearance of the cooling device and a connection example with the heat dissipator in a case where the bolt holes and the bolts are combined and bolted in the second form (120°) of FIG. 11B. Part (c) of FIG. 12 is a schematic view illustrating an outer appearance of the cooling device and a connection example with the heat dissipator in a case where the bolt holes and the bolts are combined and bolted in the third form (60°).

As illustrated in parts (a) to (c) of FIG. 12, the directions of refrigerant inflow port 9a and refrigerant outflow port 9b can be directed in any of the first direction (+Y direction), the second direction (direction forming 120° from the +Y direction), and the third direction (direction forming 60° from the +Y direction) with respect to heating element 1, and it is possible to cope with a case where a region where the cooling system can be arranged is restricted.

Note that, as illustrated in FIGS. 10A and 10B, in this example, six bolt holes 12a to 12f of base material 6 and six bolt holes 13a to 13f of second case material 8b are provided at equal intervals along the circumference, and the directions of refrigerant inflow port 9a and refrigerant outflow port 9b can be directed not only to the first direction (+Y direction), the second direction (direction forming 120° from the +Y direction), and the third direction (direction forming 60° from the +Y direction), but also to a fourth direction (direction forming 180° from the +Y direction), a fifth direction (direction forming 240° from the +Y direction), and a sixth direction (direction forming 300° from the +Y direction).

The number of bolt holes of base material 6 and the number of bolt holes of second case material 8b are not limited to the above example, and any number of bolt holes can be provided as long as the bolt holes are at equal intervals along the circumference. Alternatively, bolt holes not at equal intervals such as four corners of a rectangle that can take the first and second forms may be provided. In addition, the bolt holes for each form may be provided for each form. In this case, the bolt holes used in each form may not be used in the other forms.

Note that, although the directions of refrigerant inflow port 9a and refrigerant outflow port 9b are provided in the XY plane that is a side surface in the above example, the present invention is not limited thereto. For example, refrigerant inflow port 9a and refrigerant outflow port 9b may be arranged on a bottom surface in a −Z direction. In this case, in a case where second case material 8b is rotated with respect to base material 6 as described above, arrangement places of refrigerant inflow port 9a and refrigerant outflow port 9b on the bottom surface are changed.

In addition, as illustrated in FIG. 1, the cooling system may be formed by combining cooling device 10, pump 20, and heat dissipator 30. In this case, pump 20 and heat dissipator 30 may be normally used.

Note that, the present disclosure includes an appropriate combination of any exemplary embodiment and/or example among the various exemplary embodiments and/or examples described above, and effects of the exemplary embodiments and/or examples can be achieved.

According to the cooling device according to the present disclosure, the orientation of the pipe of the refrigerant can be appropriately changed. Accordingly, it is possible to cope with the arrangement of various cooling systems for heating elements such as displays and electronic components.

What is claimed is:

1. A cooling device comprising:
a base material providing a heating element on a first surface and a heat exchanger on a second surface opposite to the first surface, the heat exchanger receiving heat from the heating element to perform heat exchange with a refrigerant; and
a case material including a refrigerant inflow port and a refrigerant outflow port, the refrigerant inflow port supplying the refrigerant to the heat exchanger of the base material,
wherein the case material is attachable to the base material in two forms of a first form and a second form, the first form being a form in which the refrigerant inflow port and the refrigerant outflow port are attached to the base material in a first direction, and the second form being a form in which the refrigerant inflow port and the refrigerant outflow port are attached to the base material in a second direction different from the first direction.

2. The cooling device according to claim 1, wherein the heat exchanger includes a plurality of fins arranged substantially in parallel.

3. The cooling device according to claim 1, wherein
the case material includes a first case material and a second case material,
the first case material causes the refrigerant to flow through the heat exchanger, and
the second case material includes the refrigerant inflow port and the refrigerant outflow port, and is attached to the base material while holding the first case material.

4. The cooling device according to claim 3, wherein
the base material includes a plurality of first bolt holes arranged along a circumference,
the case material includes a plurality of second bolt holes corresponding to the plurality of first bolt holes, and
the base material and the case material are attachable in the first form by bolting the plurality of first bolt holes and the plurality of second bolt holes to correspond to the first form, and the base material and the case material are attachable in the second form by bolting the plurality of first bolt holes and the plurality of second bolt holes to correspond to the second form.

5. The cooling device according to claim 4, wherein the plurality of first bolt holes are arranged at equal intervals along the circumference.

6. The cooling device according to claim 4, wherein
the second case material includes a cylindrical groove through which the refrigerant flows in a center and an annular groove through which the refrigerant flows in an outer peripheral direction in a concentric circle with the cylindrical groove,
the cylindrical groove is connected to the refrigerant inflow port, and
the annular groove is connected to the refrigerant outflow port.

7. The cooling device according to claim 6, wherein the first case material defines a flow path of the refrigerant from the cylindrical groove of the second case material to the heat exchanger, and defines a flow path of the refrigerant from the heat exchanger to the annular groove.

8. The cooling device according to claim 3, wherein the base material and the case material are gripped by a gripping member.
